(19) United States
(12) Patent Application Publication
(10) Pub. No.: US 2022/0158093 A1
(43) Pub. Date: May 19, 2022

(54) MEMORY DEVICES AND METHOD OF FORMING THE SAME

(71) Applicant: GLOBALFOUNDRIES Singapore Pte. Ltd., Singapore (SG)

(72) Inventors: JIA RUI THONG, Singapore (SG); JIANXUN SUN, Singapore (SG); YI JIANG, Singapore (SG); JUAN BOON TAN, Singapore (SG)

(21) Appl. No.: 17/096,948

(22) Filed: Nov. 13, 2020

(51) Int. Cl. H01L 45/00; H01L 27/24

(52) U.S. Cl. CPC H01L 45/1273; H01L 45/16; H01L 27/2463

(57) ABSTRACT

The disclosed subject matter relates generally to memory devices and a method of forming the same. More particularly, the present disclosure relates to resistive random-access (ReRAM) memory devices. The present disclosure provides a memory device including a first electrode having tapered sides and a top surface, in which the sides taper towards each other as they meet the top surface, a dielectric layer disposed on and conforming to the tapered sides of the first electrode, a resistive layer in contact with the top surface of the first electrode and the dielectric layer, and a second electrode disposed on the resistive layer.

### FIELD OF THE INVENTION

The disclosed subject matter relates generally to memory devices and a method of forming the same. More particularly, the present disclosure relates to resistive random-access (ReRAM) memory devices.

### BACKGROUND

Semiconductor devices and integrated circuit (IC) chips have found numerous applications in the fields of physics, chemistry, biology, computing, and memory devices. An example of a memory device is a non-volatile (NV) memory device. NV memory devices are programmable and have been extensively used in electronic products due to its ability to retain data for long periods, even after the power has been turned off. Exemplary categories for NV memory may include resistive random-access memory (ReRAM), erasable programmable read-only memory (EPROM), flash memory, ferroelectric random-access memory (FeRAM), and magnetoresistive random-access memory (MRAM).

Resistive memory devices can operate by changing (or switching) between two different states: a high resistance state (HRS), which may be representative of an off or ‘0’ state; and a low resistance state (LRS), which may be representative of an on or ‘1’ state. However, these devices may experience large variations in resistive switching characteristics and may cause large fluctuations of current flow within the device, which decreases the performance of the device and increases its power consumption.

Therefore, there is a need to provide improved memory devices that can overcome, or at least ameliorate, one or more of the disadvantages as described above.

### SUMMARY

In an aspect of the present disclosure, there is provided a memory device including a first electrode having tapered sides and a top surface, in which the tapered sides taper towards each other as they meet the top surface, a dielectric layer disposed on and conforming to the tapered sides of the first electrode, a resistive layer in contact with the top surface of the first electrode and the dielectric layer, and a second electrode disposed on the resistive layer.

In another aspect of the present disclosure, there is provided a method of forming a memory device by forming a first electrode having tapered sides and a top surface, in which the sides taper towards each other as they meet the top surface, forming a dielectric layer on and conforming to the tapered sides of the first electrode, forming a resistive layer to contact the top surface of the first electrode and the dielectric layer, and forming a second electrode on the resistive layer.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of well-known features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1 is a top-down view depicting a crossbar layout of a memory device, in accordance with embodiments of the present disclosure.

FIG. 2A is a cross-sectional view of the memory device shown in FIG. 1 taken along section line AA, in accordance with the present disclosure.

FIG. 2B is a cross-sectional view of the memory device shown in FIG. 1 taken along section line BB, in accordance with the present disclosure.

FIG. 3A, FIG. 3B, FIG. 3C are perspective views depicting embodiments of the first electrode, in accordance with the present disclosure.

FIG. 4 through FIG. 9 are cross-sectional views depicting an exemplary set of steps for fabricating a memory device, in accordance with embodiments of the present disclosure.

### DETAILED DESCRIPTION

Various illustrative embodiments of the present disclosure are described below. The embodiments disclosed herein are exemplary and not intended to be exhaustive or limiting to the present disclosure.

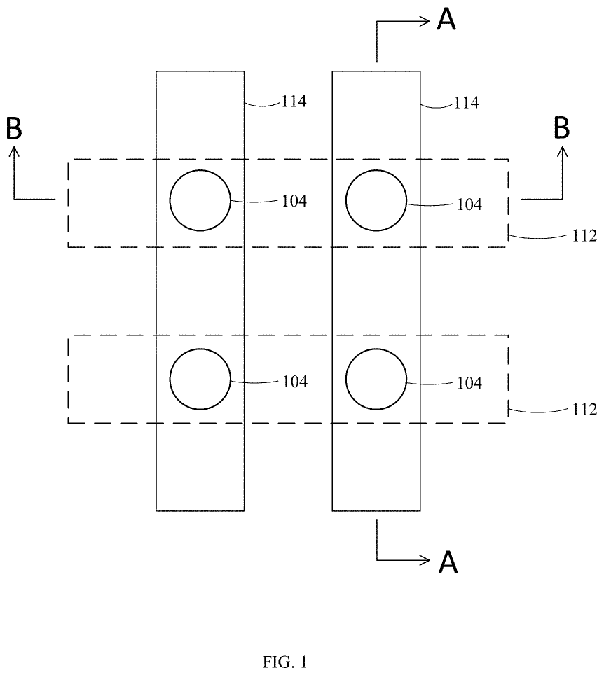

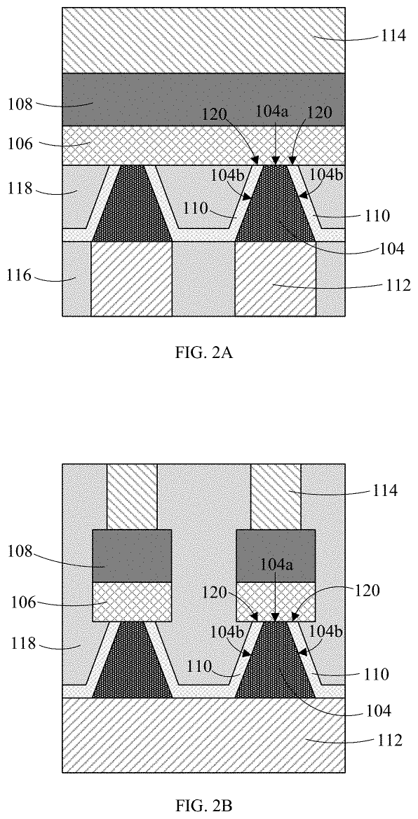

FIG. 1 illustrates an exemplary crossbar layout configuration of a memory device. Section line AA indicates the cross-section from which the view in FIG. 2A is taken from, and section line BB indicates the cross-section from which the view in FIG. 2B is taken from. The crossbar configuration may include a first interconnect structure 112, a first electrode 104 arranged above the first interconnect structure 112, and a second interconnect structure 114 arranged above the first electrode 104. The first interconnect structure 112 is outlined by broken lined rectangles to indicate that it lies beneath the first electrode 104 and the second interconnect structure 114. As shown, the second interconnect structure 114 may straddle across the first interconnect structure 112 to provide the crossbar configuration. In particular, the second interconnect structure 114 may be orthogonal to the first interconnect structure 112.

It should be noted that for simplicity, only the first interconnect structure, the first electrode and the second interconnect structure are shown in FIG. 1. As will be shown in subsequent drawings, the memory device may include other features.

Referring to FIG. 2A and FIG. 2B, the memory device includes the first electrode 104, a resistive layer 106, and a second electrode 108. The first electrode 104 has tapered sides 104b and a top surface 104a . The tapered sides 104b of the first electrode 104 taper towards each other as they meet the top surface 104a.

A dielectric layer 110 is disposed on and conforms to the tapered sides 104b of the first electrode 104. The dielectric layer 110 may include an electrically insulating material such as, but not limited to, silicon nitride (Si₃N₄), nitrogen doped silicon carbide (SiCN), or SiN_{w}CₓH_{z} (i.e., NBLoK™), wherein each of w, x, y, and z independently has a value greater than 0 and less than 0.75. The dielectric layer 110 may have an upper surface 120 that is substantially coplanar with the top surface 104a of the first electrode 104.

The resistive layer 106 is disposed on the top surface 104a of the first electrode 104. In particular, the resistive layer 110 may contact the top surface 104a of the first electrode 104 and the upper surface 120 of the dielectric layer 110. In some embodiments, the resistive layer 106 has a substantially planar upper surface. Examples of the material for the resistive layer 106 may include, but are not limited to, carbon polymers, perovskites, silicon dioxide, metal oxides, or nitrides. Some examples of metal oxides may include lanthanide oxides, tungsten oxide, zinc oxide, nickel oxide, niobium oxide, titanium oxide, hafnium oxide, aluminum oxide, tantalum oxide, zirconium oxide, yttrium oxide, scandium oxide, magnesium oxide, chromium oxide, and vanadium oxide. Examples of nitrides may include boron nitride and aluminum nitride. In some embodiments, metal oxides with a bandgap greater than 3 eV may be used. Examples of such oxides may include titanium oxide, tungsten oxide, niobium oxide, nickel oxide, zinc oxide, lanthanide oxides, hafnium oxide, aluminum oxide, tantalum oxide, zirconium oxide, and yttrium oxide.

The second electrode 108 is disposed on the resistive layer 106. The first electrode 104 and the second electrode 108 may be made of a conductive material. Examples of the conductive material may include, but not limited to, tantalum (Ta), hafnium (Hf), titanium (Ti), copper (Cu), silver (Ag), cobalt (Co), tungsten (W), ruthenium (Ru), platinum (Pt), or an alloy thereof. In an embodiment, the second electrode 108 may be made of a different material as the first electrode 104. In another embodiment, the second electrode 108 may be made of the same material as the first electrode 104.

The first electrode 104 and the second electrode 108 may be connected to various interconnect structures 112, 114 to send or receive electrical signals between other circuitry and/or active components in a memory device. The interconnect structures may include a metal such as copper, cobalt, aluminum, or an alloy thereof

A first interconnect structure 112 may be arranged below and being connected to the first electrode 104, while a second interconnect structure 114 may be arranged above and connected to the second electrode 108. In some embodiments, as shown in FIG. 2A, the resistive layer 106 and the second electrode 108 may both extend laterally to straddle across the first interconnect structure 112.

Examples of the active components (not shown) that may be connected to the first electrode 104 and the second electrode 108 may include diodes (e.g., a bi-directional diode, a single-photon avalanche diode, etc.) or transistors such as, but not limited to, planar field-effect transistor, fin-shaped field-effect transistors (FinFETs), ferroelectric field-effect transistors (FeFETs), complementary metal-oxide semiconductor (CMOS) transistors, and bi-polar junction transistors (BJT).

The memory device may further include a first inter-metal dielectric region 116 and a second inter-metal dielectric region 118. The first inter-metal dielectric region 116 may include the first interconnect structure 112, while the second inter-metal dielectric region 118 may include the dielectric layer 110, the first electrode 104, the resistive layer 106, the second electrode 108, and the second interconnect structure 114. Examples of dielectric material in the first inter-metal dielectric region 116 and the second inter-metal dielectric region 118 may include, but are not limited to, silicon dioxide, tetraethyl orthosilicate (TEOS), or a material having a chemical composition of SiCₓO_{y}H_{z}, wherein x, y, and z are in stoichiometric ratio.

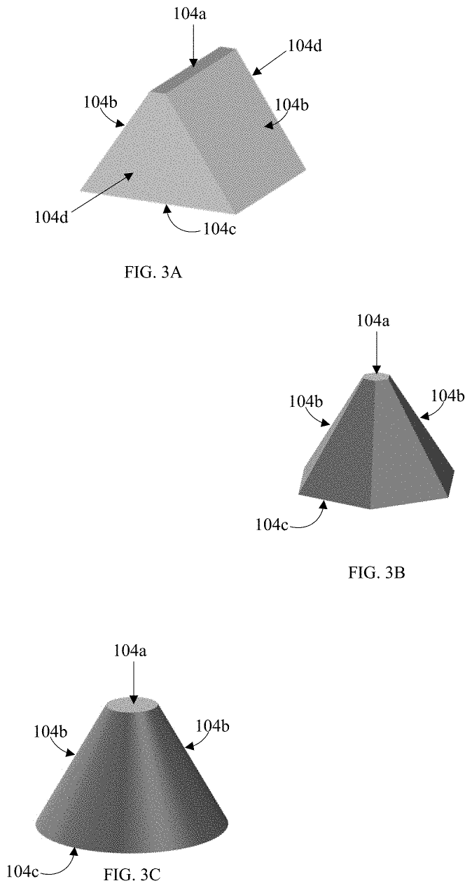

FIG. 3A, FIG. 3B, and FIG. 3C depict embodiments of the first electrode 104. In the representative embodiments, the top surface 104a of the first electrode 104 has a smaller area than a bottom surface 104c of the first electrode 104. For example, the ratio of the area of the top surface 104a of the first electrode 104 to the area of the bottom surface 104c may be in a numerical range from above 0 to about 0.1. In other words, the area of the bottom surface 104c may be greater than the area of the top surface 104a by a magnitude of at least 10.

As shown in FIG. 3A, the first electrode 104 may have tapered sides 104b and side surfaces 104d that are parallel to each other. The tapered sides 104b and side surfaces 104d meet the top surface 104a . In an embodiment, the first electrode 104 may have a trapezoidal cross sectional shape. Additionally, the bottom surface 104c and the top surface 104a may have a rectangular shape.

As shown in FIG. 3B, the first electrode 104 may be a frustum with a polygonal base. In particular, the bottom surface 104c and the top surface 104a may have a polygonal shape (e.g., pentagonal, hexagonal, heptagonal, octagonal, nonagonal, decagonal, etc.). In an embodiment, the first electrode 104 may have a frusto-pyramidal geometry.

As shown in FIG. 3C, the first electrode 104 may be frustum with an elliptical base. The bottom surface 104c and the top surface 104a may have a generally circular, elliptical, or oval shape. In an embodiment, the first electrode 104 may have a frusto-conical geometry.

Conductive paths may be configured to form in the resistive layer 106 in response to electric signals (e.g., a set voltage or current). In particular, a conductive path may form between the top surface 104a of the first electrode 104 and the second electrode 108. For example, a “set” voltage or a “reset” voltage may be applied to the first interconnect structure 112 to provide a potential difference between the first electrode 104 and the second electrode 108. This potential difference may cause the formation of the conductive path (not shown) in the resistive layer 106 to electrically link the first electrode 104 and the second electrode 108. The conductive path may be a filament that is formed by diffusion or drift of electrical charges (e.g., ions, electrons) induced by the potential difference.

The resistive layer 106 may also be configured to have a switchable resistance in response to a change in the electric signal. The formation of the filament in the resistive layer 106 may reduce the resistance of the resistive layer 106 when the electric signal is applied. Upon a reversed flow of the electric signal, the filament may be removed and the resistance of the resistive layer 106 may be increased, thereby enabling a controllable resistive nature of the resistive layer 106. The resistive layer 106 may exhibit resistive changing properties characterized by different resistance states of the material forming this layer. These resistance states (e.g., a high resistance state (HRS) or a low resistance state (LRS)) may be used to represent one or more bits of information.

Advantageously, by providing a first electrode 104 with tapered sides 104b and a dielectric layer 110 that covers and conforms to the tapered sides 104b , electrical charges may only diffuse or drift through the top surface 104a of the first electrode and not its tapered sides 104b , thereby reducing the area of contact between the resistive layer 106 and the first electrode 104. More advantageously, by arranging the dielectric layer 110 to conform to the tapered sides 104b , the dielectric layer 110 acts as an electrical insulator to prevent formation of any conductive path that could have linked the tapered sides 104b of the first electrode 104 to the second electrode 108. Additionally, the tapered sides 104b of the first electrode 104 may ensure that the top surface 104a have the strongest localization of electric fields (i.e., the largest concentration of electric charges) within the first electrode 104.

With a reduced area of contact between the resistive layer 106 and the first electrode 104, the conductive paths formed between the first electrode 104 and the second electrode 108 can be confined, and do not form randomly along the length of the resistive layer 106. The confinement of the conducting path may help to reduce the stochasticity of its formation, which in turn reduces the cycle-to-cycle and device-to-device variability of the memory devices in the high resistive state. In other words, the variability of the resistance of the resistive layer 106 in the high resistive state may be reduced. This may enable a stable switching of the resistive states in the resistive layer 106 during operation of the device and may reduce its overall power consumption.

The memory device described herein may be a resistive memory device. Examples of the resistive memory device may include, but are not limited to, oxide random-access memory (OxRAM) or conductive bridge random-access memory (CBRAM).

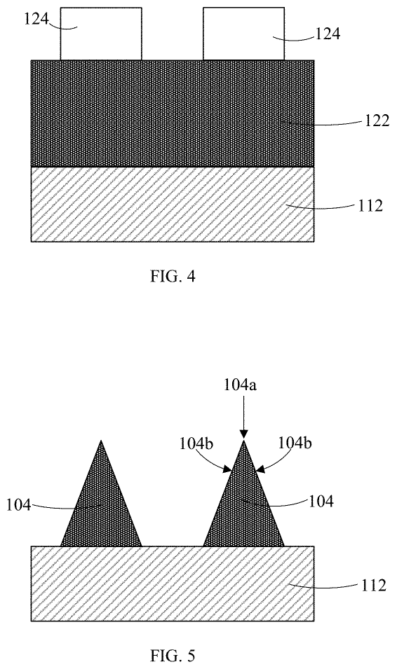

FIGS. 4 through 9 show a set of steps that may be used to create the memory devices as provided for in embodiments of the present disclosure. FIGS. 4 through 9 depict cross-sectional views taken along the section line BB shown in FIG. 1.

As used herein, “deposition techniques” refer to the process of applying a material over another material (or the substrate). Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Additionally, “patterning techniques” includes deposition of material or photoresist, patterning, exposure, development, etching, cleaning, and/or removal of the material or photoresist as required in forming a described pattern, structure, or opening. Examples of techniques for patterning include, but not limited to, wet etch lithographic processes, dry etch lithographic processes, or direct patterning processes. Such techniques may use mask sets and mask layers.

Referring to FIG. 4, a first interconnect structure 112 may be provided. The first interconnect structure 112 may be formed in a first inter-metal dielectric region (not shown in FIG. 4). A conductive material layer 122 may be formed on the first interconnect structure 112 using the deposition techniques described herein. A photoresist may be deposited on the conductive material layer 122 and then patterned to define a mandrel mask 124.

Referring to FIG. 5, the conductive material layer 122 may be patterned using the patterning techniques described herein. For example, a dry etch may be used to pattern the conductive material layer 122 to form a first electrode 104 with tapered sides 104b and a top 104a . The top 104a and the tapered sides 104b may be formed due to the erosion of the mandrel mask 124 during the etch. Various etchants may be employed during the etch, such as oxygen (02) gas and carbon tetrafluoride (CF4) gas. For example, carbon tetrafluoride may be used to etch the mandrel mask 124 while oxygen gas may be used to etch the conductive material layer 122. The mandrel mask 124 may be removed after the etching. The first electrode 104 may be etched such that the tapered sides 104b converge to form a pointed tip or an edge at the top 104a.

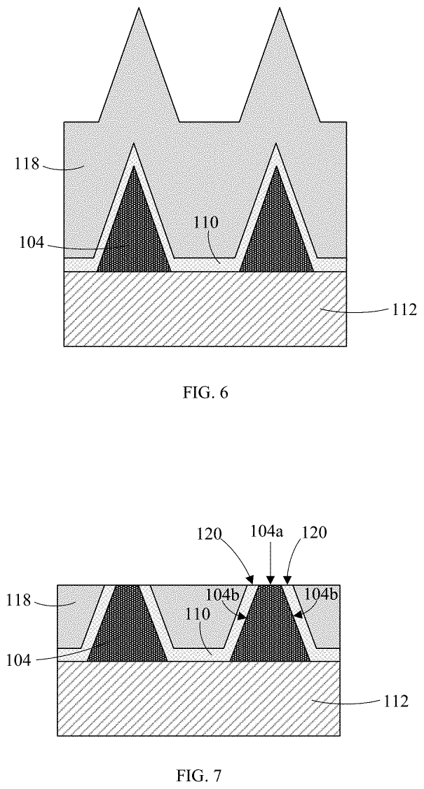

Referring to FIG. 6, a dielectric layer 110 may be deposited on the first electrode 104 and the first interconnect structure 112. The dielectric layer 110 may be deposited using a conformal deposition process, such as an ALD process or a highly-conformal CVD process. The deposited dielectric layer 110 conformally covers the first electrode 104 including its top 104a and tapered sides 104b . A second inter-metal dielectric region 118 may be deposited on the dielectric layer 110. The dielectric layer 110 may protect the tapered sides 104b of the first electrode 104 from damage (e.g., sputtering of the sides) during subsequent fabrication steps.

Referring to FIG. 7, a chemical mechanical planarization (CMP) process may be performed on the second inter-metal dielectric region 118. The CMP process may continue to remove materials in the second inter-metal dielectric region 118 and stop upon reaching the dielectric layer 110. The dielectric layer 110 may serve as a stop layer to reduce the variation of the CMP process. Upon reaching the dielectric layer 110, the CMP process may be resumed for a predetermined time to planarize an upper surface 120 of the dielectric layer 110 and expose the top 104a of the first electrode 104. Accordingly, the first electrode 104 may have a substantially planar top surface 104a . The top surface 104a may be substantially coplanar with the upper surface 120 of the dielectric layer 110.

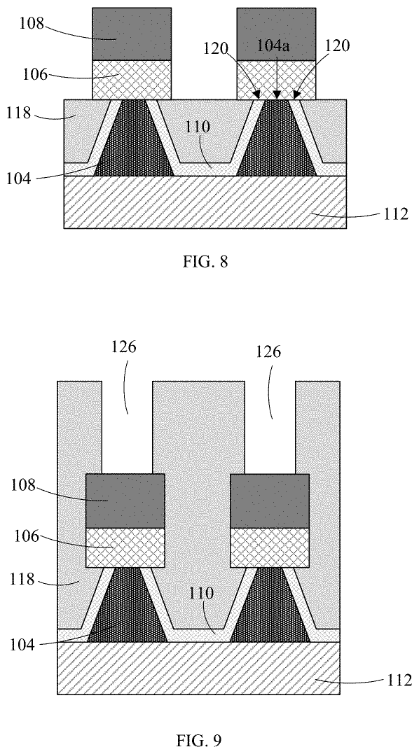

Referring to FIG. 8, a resistive layer 106 is formed upon the top surface 104a and the upper surface 120 of the dielectric layer 110. A second electrode 108 is also formed upon the resistive layer 106. For example, the resistive layer 106 and the second electrode 108 may be formed by depositing layers of material using the deposition techniques described herein, followed by patterning the deposited layers using the patterning techniques described herein.

Referring to FIG. 9, additional deposition of a dielectric material may be performed to embed the second electrode 108 and the resistive layer 106 in the second inter-metal dielectric region 118. Thereafter, the second inter-metal dielectric region 118 may be patterned using patterning techniques to define openings 126 above the second electrode 108. The openings 126 may be subsequently filled with a metal to form a second interconnect structure on the second electrode.

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description.

Additionally, the various tasks and processes described herein may be incorporated into a more comprehensive procedure or process having additional functionality not described in detail herein. In particular, various processes in the manufacture of integrated circuits are well-known and so, in the interest of brevity, many processes are only mentioned briefly herein or omitted entirely without providing the well-known process details.

As will be readily apparent to those skilled in the art upon a complete reading of the present application, the disclosed semiconductor devices and methods of forming the same may be employed in manufacturing a variety of different integrated circuit products, including, but not limited to, memory cells, NV memory devices, FinFET transistor devices, CMOS devices, etc.

What is claimed is:

1. A memory device comprising:
a first electrode having tapered sides and a top surface, wherein the tapered sides taper towards each other as they meet the top surface;
a dielectric layer disposed on and conforming to the tapered sides of the first electrode;
a resistive layer in contact with the top surface of the first electrode and the dielectric layer; and
a second electrode disposed on the resistive layer.

2. The device of claim 1, wherein the dielectric layer has an upper surface that is substantially coplanar with the top surface of the first electrode.

3. The device of claim 2, wherein the resistive layer has a substantially planar upper surface.

4. The device of claim 3, further comprising:
a first interconnect structure arranged below and being connected to the first electrode; and
a second interconnect structure arranged above and being connected to the second electrode.

5. The device of claim 4, wherein the second interconnect structure straddles across the first interconnect structure.

6. The device of claim 5, wherein the resistive layer and the second electrode extend laterally to straddle across the first interconnect structure.

7. The device of claim 1, wherein the top surface of the first electrode has a smaller area than a bottom surface of the first electrode.

8. The device of claim 7, wherein the first electrode is a frustum with an elliptical base.

9. The device of claim 8, wherein the first electrode has a frusto-conical geometry.

10. The device of claim 7, wherein the first electrode is a frustum with a polygonal base.

11. The device of claim 10, wherein the first electrode has a frusto-pyramidal geometry.

12. The device of claim 7, wherein the first electrode has a trapezoidal cross sectional shape.

13. The device of claim 1, wherein the top surface of the first electrode is substantially planar.

14. A method of forming a memory device comprising:
forming a first electrode having tapered sides and a top surface, wherein the tapered sides taper towards each other as they meet the top surface;
forming a dielectric layer on and conforming to the tapered sides of the first electrode;
forming a resistive layer to contact the top surface of the first electrode and the dielectric layer; and
forming a second electrode on the resistive layer.

15. The method of claim 14, wherein the forming of the dielectric layer further comprises:
depositing the dielectric layer to cover the top surface of the first electrode;
planarizing an upper surface of the dielectric layer to expose the top surface of the first electrode, wherein the upper surface of the dielectric layer is substantially coplanar with the top surface of the first electrode.

16. The method of claim 14, further comprising:
providing an inter-metal dielectric region comprising a first interconnect structure before forming the first electrode; and
forming a second interconnect structure on the second electrode.

17. The method of claim 16, wherein the forming of the first electrode further comprises:
depositing a conductive material on the inter-metal dielectric region and the first interconnect structure; and
patterning the conductive material to form the tapered sides of the first electrode, wherein the first electrode has a bottom surface that contacts the first interconnect structure.

18. The method of claim 15, wherein the deposition of the dielectric layer includes an atomic layer deposition process.

19. The method of claim 15, wherein the deposition of the dielectric layer includes a chemical vapor deposition process.

20. The method of claim 15, wherein the planarization of the upper surface of the dielectric layer include performing a chemical mechanical planarization process.
